(19) United States
(12) Patent Application Publication
(10) Pub. No.: US 2015/0028292 A1
(43) Pub. Date: Jan. 29, 2015

(54) ORGANIC LIGHT-EMITTING DISPLAY DEVICE AND MANUFACTURING METHOD THEREOF

(71) Applicant: Samsung Display Co., Ltd., Yongin-City (KR)

(72) Inventor: Yoon-Ho Kang, Yongin-City (KR)

(73) Assignee: Samsung Display Co., Ltd., Yongin-City (KR)

(21) Appl. No.: 14/061,624

(22) Filed: Oct. 23, 2013

(30) Foreign Application Priority Data
Jul. 25, 2013 (KR) 10-2013-0088082

(51) Int. Cl. H01L 51/50; H01L 27/32; H01L 51/56

(52) U.S. Cl. CPC H01L 51/5012; H01L 51/56; H01L 27/3262; H01L 51/0005
USPC 257/40; 438/34

(57) ABSTRACT

An organic light-emitting display device includes a thin film transistor, a planarization layer on the thin film transistor and having an integral pixel sectioning portion defining a boundary of a pixel area, a pixel electrode connected to the thin film transistor in the pixel area inside the pixel sectioning portion, a light-emitting layer on the pixel electrode, and an opposite electrode on the light emitting layer.

### CROSS-REFERENCE TO RELATED APPLICATION

This application claims priority to and the benefit of Korean Patent Application No. 10-2013-0088082, filed on Jul. 25, 2013 in the Korean Intellectual Property Office, the entire content of which is incorporated herein by reference.

### BACKGROUND

1. Technical Field

One or more embodiments of the present invention relate to an organic light-emitting display device (OLED) and a manufacturing method thereof.

2. Description of the Related Art

In general, an organic light-emitting display device (OLED) produces color by recombining holes and electrons injected by an anode and cathode in a light emitting layer to emit light. The OLED is a multilayer structure in which a light-emitting layer is positioned between a pixel electrode (i.e., the anode) and an opposite electrode (i.e., the cathode).

A pixel unit of the OLED includes red, green, and blue subpixels and the desired color is displayed via a color combination of the three subpixels. In other words, in each subpixel, a light-emitting layer emitting any one of red light, green light, or blue light is positioned between two electrodes. An appropriate combination of the three color lights displays the desired color of the pixel unit.

The area of each subpixel is defined by a pixel definition layer and the light-emitting layer is formed in the sectioned area created by the pixel definition layer. However, according to the general order of processing, the pixel definition layer is formed after the pixel electrode is formed, and after the area for formation of the light-emitting layer is patterned. As such, a residue of the pixel definition layer may remain on the pixel electrode during formation of the light-emitting layer. This creates a non-contact section between the light-emitting layer and the pixel electrode (due to the remaining residue of the pixel definition layer), which deteriorates the characteristics of the final product.

### SUMMARY

According to one or more embodiments of the present invention, an organic light-emitting display device (OLED) has generally uniform and stable contact between the light-emitting layer and the pixel electrode. Other embodiments of the present invention are directed to a manufacturing method of the OLED.

Additional aspects will be set forth in part in the description which follows and, in part, will be apparent from the description, or may be learned by practice of the presented embodiments.

According to one or more embodiments of the present invention, an organic light-emitting display device includes a thin film transistor, a planarization layer covering the thin film transistor and having an integral pixel sectioning portion defining a boundary of a pixel area, a pixel electrode in the pixel area inside the pixel sectioning portion and connected to the thin film transistor, a light-emitting layer on the pixel electrode, and an opposite electrode on the light emitting layer.

The planarization layer may be a lyophobic organic layer.

The light-emitting layer may be formed by inkjet printing.

According to one or more embodiments of the present invention, a method of manufacturing an organic light-emitting display device includes forming a thin film transistor on a substrate, forming a planarization layer covering the thin film transistor, forming a pixel sectioning portion defining a boundary of a pixel area by patterning the planarization layer, forming a pixel electrode connected to the thin film transistor in the pixel area inside the pixel sectioning portion, forming a light-emitting layer on the pixel electrode, and forming an opposite electrode on the light-emitting layer.

The planarization layer may be a lyophobic organic layer.

The light-emitting layer may be formed by inkjet printing.

In forming the pixel sectioning portion, a portion of the planarization layer that becomes the pixel area may be etched, leaving a portion that becomes the pixel sectioning portion.

The pixel electrode may be formed by deposition or inkjet printing.

### BRIEF DESCRIPTION OF THE DRAWINGS

These and/or other aspects will become apparent and more readily appreciated from the following description taken in conjunction with the accompanying drawings, in which:

FIG. 1 is a cross-sectional view of an organic light-emitting display device (OLED) according to an embodiment of the present invention;

FIGS. 2A to 2F are cross-sectional views of the OLED of FIG. 1, illustrating various stages in a process of manufacturing the OLED according to an embodiment of the present invention; and

FIG. 3 is a magnified cross-sectional view of a light-emitting layer of the OLED of FIG. 1.

### DETAILED DESCRIPTION

Reference will now be made to embodiments, examples of which are illustrated in the accompanying drawings, wherein like reference numerals refer to like elements throughout. The described embodiments may be modified in different ways and should not be construed as limited to the descriptions set forth herein. Accordingly, the embodiments are presented for illustrative and descriptive purposes, with reference to the figures, to explain different aspects of the present description. Expressions such as “at least one of,” when preceding a list of elements, modify the entire list of elements and do not modify the individual elements of the list.

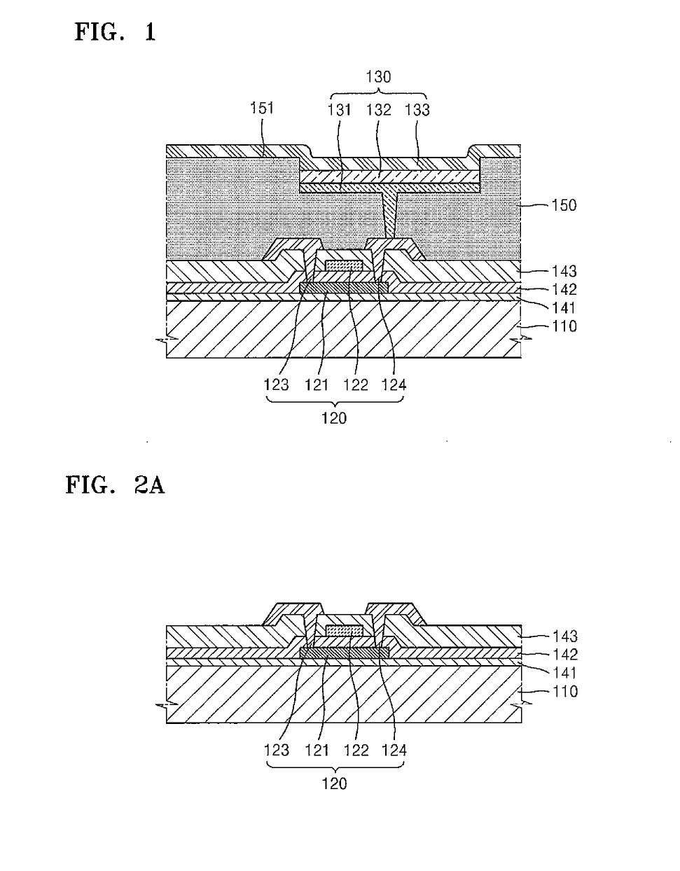

FIG. 1 is a cross-sectional view of an organic light-emitting display device (OLED) according to an embodiment of the present invention. Referring to FIG. 1, an OLED includes a substrate 110, a thin film transistor (TFT) 120 on the substrate 110, and an organic light-emitting diode 130. For ease of description, FIG. 1 illustrates only one subpixel in the OLED. However, a plurality of subpixels may be present in rows and columns on the substrate 110.

The TFT 120 includes an active layer 121 on the substrate 110, a gate electrode 122 facing the active layer 121, and a source electrode 123 and a drain electrode 134 respectively connected to the active layer 121 and a pixel electrode 131 of the organic light-emitting diode 130. A source region and a drain region (to which high concentrations of impurities are injected) are formed at the opposite sides of the active layer 121, and thus, the source region and the drain region are connected to the source electrode 123 and the drain electrode 124, respectively. Accordingly, when an appropriate voltage is applied to the gate electrode 122, the region between the source region and the drain region functions as a channel so that current flows from the source electrode 123 to the drain electrode 124. The source electrode 123 and the drain electrode 124 are together referred to as source/drain electrodes 123 and 124.

A planarization layer 150 is formed on the TFT 120 and forms a flat surface by covering the TFT 120 and sections a pixel area for forming the organic light-emitting diode 130. In other words, the planarization layer 150 covers an upper surface of the TFT 120 and simultaneously forms a boundary portion of the pixel area using a pixel sectioning portion 151. As such, an organic light-emitting diode 130 including the pixel electrode 131, a light-emitting layer 132, and an opposite electrode 133 may be stably formed in the pixel area. This effect will be described later.

As illustrated in FIG. 3, a hole injection layer 132a, a hole transport layer 132b, an electron transport layer 132c, and an electron injection layer 132d may be further provided in the lower and upper portions of the light-emitting layer 132. The layers between the pixel electrode 131 and the opposite electrode 133, including the light-emitting layer 132, may be formed by an inkjet printing process.

The planarization layer 150 may be formed of a lyophobic organic layer. In this case, the liquid of the light-emitting layer 132 is generally prevented from intruding into the planarization layer 150 during formation of the light-emitting layer 132 by inkjet printing. A material of the lyophobic organic layer may be an organic substance (such as, e.g., polyimide) in which a fluorene compound is mixed.

The organic light-emitting diode 130 includes the pixel electrode 131, the light-emitting layer 132 formed on the pixel electrode 131, and the opposite electrode 133 formed on the light emitting layer 132. Accordingly, when a voltage is applied to the pixel electrode 131 from the TFT 120 (and thus an appropriate voltage condition is formed between the pixel electrode 131 and the opposite electrode 133), the light-emitting layer 132 emits light.

In a front light-emitting structure (in which an image is presented in a direction toward the opposite electrode 133), the pixel electrode 131 and the opposite electrode 144 may be formed as a reflective electrode and a light transmitting electrode, respectively.

As described above, the hole injection layer 132a, the hole transport layer 132b, the electron transport layer 132c, and the electron injection layer 132d may be selectively stacked (or may all be stacked) in the lower and upper portions of the light-emitting layer 132.

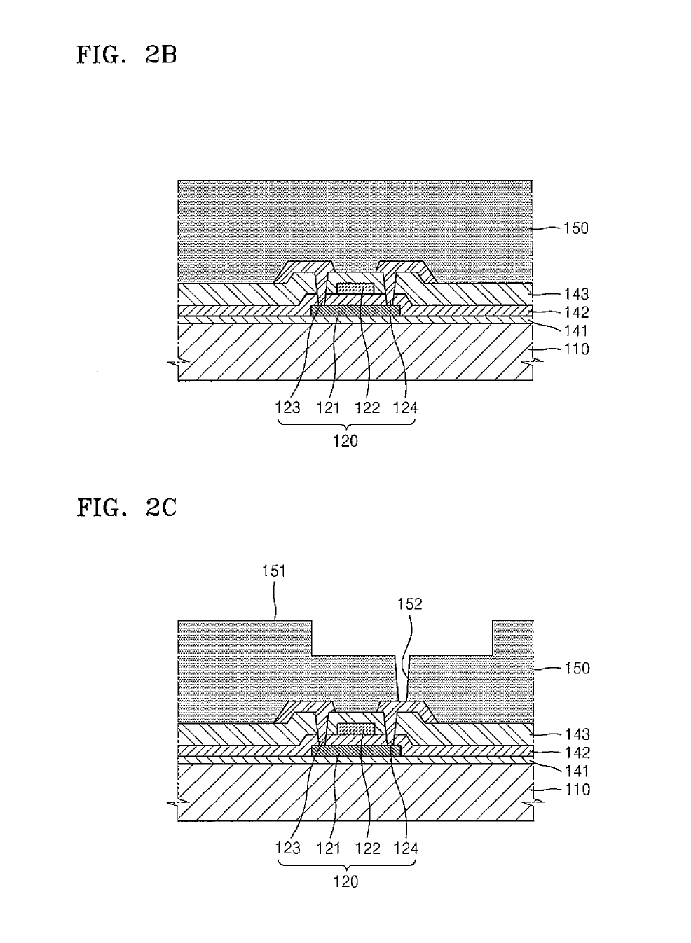

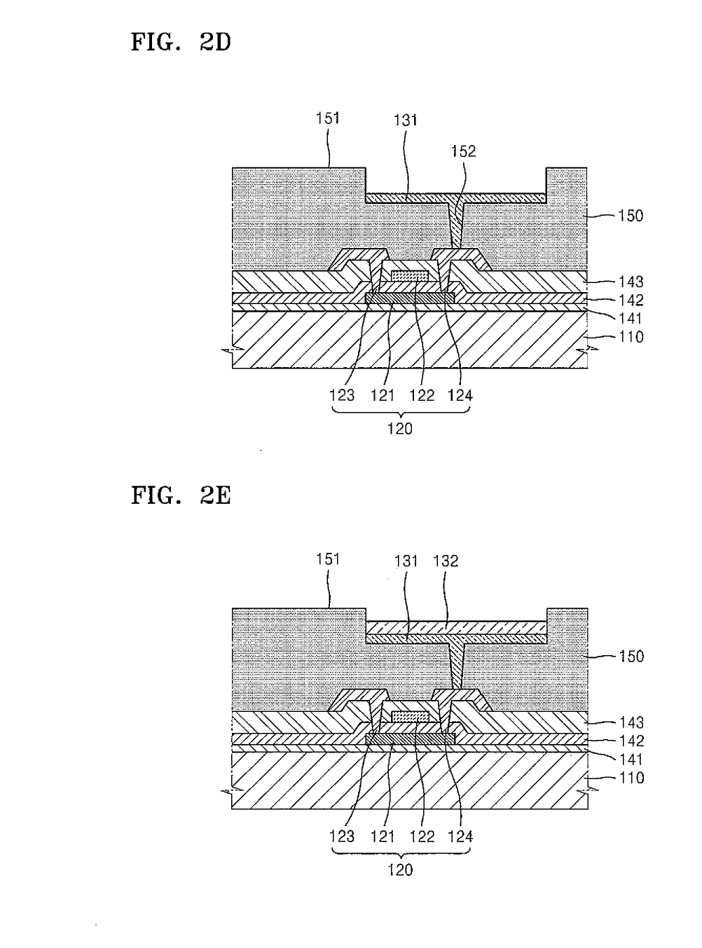

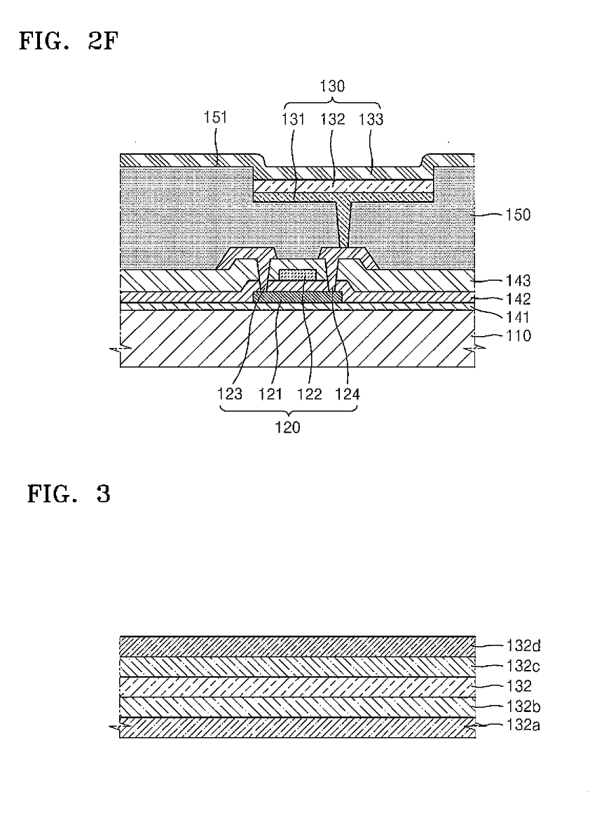

Reference number 141 denotes a buffer layer, and reference numerals 142 and 143 denote insulation layers. The OLED configured as above may be manufactured by the process illustrated in FIGS. 2A to 2F. As illustrated in FIG. 2A, the active layer 121, the gate electrode 122, and the source/drain electrodes 123 and 124 are sequentially formed on the substrate 110. The active layer 121 may be formed of, for example, an amorphous silicon thin film or a polycrystalline silicon thin film. The source region and the drain region are formed by doping the opposite sides of the active layer 121 with N- or P-type impurities at high concentrations, as described above. The active layer 121 may be formed of an oxide semiconductor. For example, the oxide semiconductor may include an oxide of a Group 12, 13, or 14 metal element, such as zinc (Zn), indium (In), gallium (Ga), tin (Sn), cadmium (Cd), germanium (Ge), hafnium (Hf), or a combination thereof. For example, the oxide semiconductor may include a gallium-indium-zinc-oxide (or “G—I—Z—O”), i.e., [(In₂O₃)ₐ(Ga₂O₃)_{b}(ZnO)_{c}], where “a”, “b”, and “c” are real numbers, a≧0, b≧0, and c>0.

Next, as illustrated in FIG. 2B, the planarization layer 150 is formed on the TFT 120, and is formed of a lyophobic organic layer. Then, the planarization layer 150 is partially etched by photolithography to form the pixel sectioning portion 151, as illustrated in FIG. 2C. In other words, the pixel sectioning portion 151 of the planarization layer 150 is not etched, whereas a pixel area (where the organic light-emitting diode 130 will be formed) is etched away, and is therefore at a lower depth relative to the pixel sectioning portion 151. Accordingly, the boundary of the pixel area is formed without having to separately form a pixel definition layer. A contact hole 152 connected to the drain electrode 124 is formed together with the pixel sectioning portion 151. When photolithography is used to create portions having different etching depths using a halftone mask, the pixel sectioning portion 151 (which forms the boundary of the pixel portion) and the contact hole 152 connected to the drain electrode 124 may be formed together.

Next, as illustrated in FIG. 2D, the pixel electrode 131 of the organic light-emitting diode 130 is formed in the pixel area surrounded by the pixel sectioning portion 151. The pixel electrode 141 may be formed by deposition or inkjet printing. The pixel electrode 131 is connected to the drain electrode 124 via the contact hole 152.

As such, after the pixel electrode 131 is formed, as illustrated in FIG. 2E, the light-emitting layer 132 is formed on the pixel electrode 131. The light-emitting layer 132 may be formed alone, or, as illustrated in FIG. 3, a hole injection layer 132a, a hole transport layer 132b, an electron transport layer 132c, and an electron injection layer 132d may be selectively stacked (or may all be stacked) in the lower and upper portions of the light-emitting layer 132. The hole injection layer 132a, the hole transport layer 132b, the electron transport layer 132c, and the electron injection layer 132d may all be formed by inkjet printing. In other words, droplets of the material of the corresponding layer are dropped by an inkjet head (not shown) onto the pixel area and then solidified, thereby forming the desired layer. Since the planarization layer 150 that sections the pixel area is formed of a lyophobic organic layer, the inkjet droplets may be generally prevented from intruding into the planarization layer 160. Accordingly, the light-emitting layer 132 may be stably formed generally only within the pixel area. Also, since the pixel area is formed flat by etching the planarization layer 150 in advance, the bottom surface of the pixel area may be generally prevented from being formed unevenly according to the shape of the TFT 120 (which is formed thereunder). Accordingly, there is generally no non-contact area between the pixel electrode 131 and the light-emitting layer 132 due to the residue of the planarization layer 150. Thus, the light-emitting layer 132 is generally stable and uniform.

Next, as illustrated in FIG. 2F, the opposite electrode 133 is formed, thereby completing the organic light-emitting diode 130.

In the light-emitting layer 132, subpixels emitting red, green, and blue light together may constitute a single pixel unit. Instead of separately forming a light-emitting material for each subpixel, the light-emitting layer 132 may be commonly formed on the entire surface, regardless of the position of the subpixel. The light-emitting layer 132 may include, for example, layers including the red, green and blue light-emitting materials that are vertically stacked or mixed with one another. In order to emit white light, a combination of other colors may be used. Also, a color conversion layer, or a color filter that converts the emitted white light into a predetermined color may be further provided.

An encapsulation member (not shown) may be formed on the organic light-emitting diode 130. An insulation substrate made of a glass material, or a thin film encapsulation layer may be used as the encapsulation member. For the thin film encapsulation layer, for example, the encapsulation member may be a monolayer or multilayer of an inorganic material, such as a metal oxide or a metal nitride. For example, the inorganic material may include any one of SiNx, Al₂O₃, SiO₂, or TiO₂. The top layer of the thin film encapsulation layer (which is exposed to the outside) may be an inorganic layer in order to prevent intrusion of moisture into the organic light-emitting diode 130. The thin film encapsulation layer may include at least one sandwich structure in which at least one organic layer is positioned between at least two inorganic layers. The thin film encapsulation layer may include a first inorganic layer, a first organic layer, and a second inorganic layer, formed sequentially from an upper surface of the organic light-emitting diode 130. Also, the thin film encapsulation layer may include a first inorganic layer, a first organic layer, a second inorganic layer, a second organic layer, and a third inorganic layer, formed sequentially from the upper surface of the organic light-emitting diode 130. Also, the thin film encapsulation layer may include a first inorganic layer, a first organic layer, a second inorganic layer, a second organic layer, a third inorganic layer, a third organic layer, and a fourth inorganic layer, formed sequentially from the upper surface of the organic light-emitting diode 130.

A metal halide layer (e.g., LiF) may be further provided between the organic light-emitting diode 130 and the first inorganic layer. The metal halide layer may generally prevent the organic light-emitting diode 130 from being damaged when the first inorganic layer is formed by sputtering or plasma deposition.

The first organic layer may have an area smaller than an area of the second inorganic layer, and the second organic layer may have an area smaller than an area of the third inorganic layer. Also, the first organic layer may be completely covered by the second inorganic layer, and the second organic layer may be completely covered by the third inorganic layer. The organic layer may be formed of a polymer, such as polyethylene terephthalate, polyimide, polycarbonate, epoxy, polyethylene, or polyacrylate. For example, the organic layer may be formed of polyacrylate, and may include a polymerization product of a monomer composite including a diacrylate-based monomer and a triacrylate-based monomer. The monomer composite may further include a monoacrylate-based monomer. Also, the monomer composite may further include a photoinitiator, such as TPO (2,4,6-trimethylbenzoyl-diphenyl-phosphineoxide), but the present invention is not limited thereto.

In the above structure, the planarization layer is etched to form a flat pixel area without forming a separate pixel definition layer, and then, the pixel electrode and the light-emitting layer are formed. As such, uniform and stable contact between the light-emitting layer and the pixel electrode may be achieved. Thus, as described above, reliability of the OLED may be improved by effectively and substantially preventing the creation of non-contact areas between the light-emitting layer and the pixel electrode.

The exemplary embodiments described herein should be considered in a descriptive sense only and not for purposes of limitation. Indeed, descriptions of features or aspects within each embodiment should typically be considered as available for other similar features or aspects in other embodiments.

While one or more embodiments of the present invention have been described with reference to the figures, it will be understood by those of ordinary skill in the art that various changes may be made to the described embodiments without departing from the spirit and scope of the present invention as defined by the following claims.

What is claimed is:

1. An organic light-emitting display device, comprising:
a thin film transistor;
a planarization layer on the thin film transistor and comprising an integral pixel sectioning portion defining a boundary of a pixel area;
a pixel electrode in the pixel area inside the pixel sectioning portion and connected to the thin film transistor;
a light-emitting layer on the pixel electrode; and
an opposite electrode on the light emitting layer.

2. The organic light-emitting display device of claim 1, wherein the planarization layer is a lyophobic organic layer.

3. The organic light-emitting display device of claim 1, wherein the light-emitting layer is formed by inkjet printing.

4. A method of manufacturing an organic light-emitting display device, the method comprising:
forming a thin film transistor on a substrate;
forming a planarization layer on the thin film transistor;
patterning the planarization layer to form a pixel sectioning portion defining a boundary of a pixel area;
forming a pixel electrode in the pixel area inside the pixel sectioning portion, the pixel electrode being connected to the thin film transistor;
forming a light-emitting layer on the pixel electrode; and
forming an opposite electrode on the light-emitting layer.

5. The method of claim 4, wherein the planarization layer is a lyophobic organic layer.

6. The method of claim 4, wherein the light-emitting layer is formed by inkjet printing.

7. The method of claim 4, wherein the patterning the planarization layer comprises etching a portion of the planarization layer corresponding to the pixel area, and not etching a portion of the planarization layer corresponding to the pixel sectioning portion.

8. The method of claim 4, wherein the pixel electrode is formed by deposition or inkjet printing.
